(19) United States
(12) Patent Application Publication
(10) Pub. No.: US 2026/0173354 A1
(43) Pub. Date: Jun. 18, 2026

(54) SEMICONDUCTOR MEMORY DEVICE AND METHOD FOR MANUFACTURING THE SAME

(71) Applicant: Samsung Electronics Co., Ltd., Suwon-si (KR)

(72) Inventors: In Geun CHOI, Suwon-si (KR); Ho-in RYU, Suwon-si (KR); Hyo-Sun MIN, Suwon-si (KR); Ji Min CHOI, Suwon-si (KR)

(21) Appl. No.: 19/349,619

(22) Filed: Oct. 3, 2025

(30) Foreign Application Priority Data
Dec. 13, 2024 (KR) 10-2024-0185945

(51) Int. Cl. H10B 12/00; H01L 23/528; H01L 23/532

(52) U.S. Cl. CPC H10B 12/34; H10B 12/02; H10B 12/315; H10B 12/482; H10W 20/425; H10W 20/435; H10W 20/48

(57) ABSTRACT

Provided is a semiconductor memory device. The semiconductor memory device includes a first substrate including a substrate having an active region and extending in a first horizontal direction and a second horizontal direction intersecting each other, a contact plug connected to the active region, a bitline structure disposed adjacent to the contact plug in the first horizontal direction and extending along the second horizontal direction, a landing pad disposed on the bitline structure and connected to the contact plug, spacer patterns spaced apart from each other on an upper surface of the bitline structure and contacting at least one sidewall of the landing pad, a separation pattern extending to inner sidewalls of the bitline structure between the spacer patterns, and an oxide film disposed between the spacer patterns and the separation pattern, wherein the oxide film is not disposed between the separation pattern and the bitline structure.

### CROSS-REFERENCE TO RELATED APPLICATION

This application claims priority under 35 U.S.C. § 119 from Korean Patent Application No. 10-2024-0185945, filed on Dec. 13, 2024, in the Korean Intellectual Property Office, and all the benefits accruing therefrom under 35 U.S.C. § 119, the contents of which in its entirety are herein incorporated by reference.

### BACKGROUND

### 1. Field

The present disclosure relates to a semiconductor memory device and a method for manufacturing the same.

### 2. Description of the Related Art

As semiconductor devices become increasingly highly integrated, individual circuit patterns are being miniaturized to implement more semiconductor devices within the same area. That is, as the integration density of semiconductor devices increases, the design rules for the components of semiconductor devices are decreasing.

In highly scaled semiconductor devices, the process of forming a plurality of wiring lines and a plurality of contacts interposed therebetween is becoming increasingly complex and challenging.

### SUMMARY

An objective of the present disclosure is to provide a semiconductor memory device with improved reliability and performance.

Another objective of the present disclosure is to provide a method for manufacturing a semiconductor memory device with improved reliability and performance.

The objectives of the present disclosure are not limited to those mentioned above, and other objectives not explicitly stated will be clearly understood by those skilled in the art based on the following description.

A semiconductor memory device according to some embodiments of the present disclosure includes a substrate having an active region and extending in a first horizontal direction and a second horizontal direction intersecting each other, a contact plug connected to the active region, a bitline structure disposed adjacent to the contact plug in the first horizontal direction and extending along the second horizontal direction, a landing pad disposed on the bitline structure and connected to the contact plug, spacer patterns spaced apart from each other on an upper surface of the bitline structure and contacting at least one sidewall of the landing pad, a separation pattern extending to inner sidewalls of the bitline structure between the spacer patterns, and an oxide film disposed between the spacer patterns and the separation pattern, wherein the oxide film is not disposed between the separation pattern and the bitline structure.

A semiconductor memory device according to some other embodiments of the present disclosure includes a substrate having an active region and extending in a first horizontal direction and a second horizontal direction perpendicularly intersecting each other, contact plugs connected to the active region, bitline structures alternately arranged with the contact plugs in the first horizontal direction and extending along the second horizontal direction, landing pads respectively connected to the contact plugs on the bitline structures, and including a barrier film in contact with sidewalls and upper surfaces of the bitline structures, and a first metal film on the barrier film, a second metal film disposed between the contact plugs and the landing pads, spacer patterns spaced apart from each other on the upper surfaces of the bitline structures and contacting sidewalls of the landing pads, a separation pattern extending along a vertical direction to an inner sidewall of one of the bitline structures, between the spacer patterns, and an oxide film between the spacer patterns and the separation pattern, wherein the separation pattern includes a first portion in contact with the inner sidewall of the one of the bitline structures and an inner sidewall of one of the landing pads, and a second portion disposed on the first portion and in contact with the oxide film.

A method for manufacturing a semiconductor memory device according to some embodiments of the present disclosure includes forming a bitline structure extending along a first horizontal direction, on a substrate, forming a contact plug adjacent to the bitline structure in a second horizontal direction and connected to an active region, on the substrate, forming a landing pad including a pre-barrier film, extending along sidewalls and an upper surface of the bitline structure, and a pre-metal film on the pre-barrier film, on the contact plug, forming a metal film having a first recess that exposes a portion of the bitline structure, by removing at least portions of the pre-metal film and the pre-barrier film, forming a pre-spacer film within the first recess, along a surface of the metal film, forming spacer patterns having second recesses that expose inner sidewalls of the bitline structure, by removing at least portions of the pre-spacer film, the bitline structure, and the pre-barrier film, forming a separation pattern between the spacer patterns, within the second recesses, and forming an oxide film on the spacer patterns, wherein the oxide film is not formed between the bitline structure and the separation pattern.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a schematic layout of a semiconductor memory device according to some example embodiments;

FIG. 2 is an exemplary cross-sectional view taken along A-A′ of FIG. 1;

FIG. 3 is an enlarged view of region S in FIG. 2; and

FIGS. 4 through 18 are diagrams for explaining intermediate steps of a method for manufacturing a semiconductor memory device according to some example embodiments.

### DETAILED DESCRIPTION

Embodiments of the present disclosure will now be described in detail with reference to the accompanying drawings. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

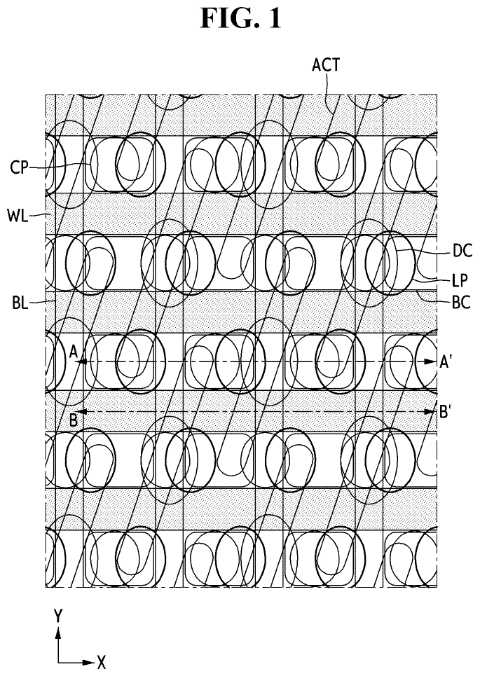

FIG. 1 is a schematic layout of a semiconductor memory device according to some example embodiments.

Referring to FIG. 1, the semiconductor memory device according to some embodiments may include a plurality of active regions ACT. The active regions ACT may be arranged diagonally with respect to a first horizontal direction X and a second horizontal direction Y. A plurality of wordlines WL may extend lengthwise in parallel to each other across the active regions ACT along the first horizontal direction X. Above the wordlines WL, a plurality of bitlines BL may extend lengthwise in parallel to each other along the second horizontal direction Y, which intersects the first horizontal direction X. The bitlines BL may be connected to the active regions ACT through direct contacts DC.

A plurality of buried contacts BC may be formed between each pair of adjacent bitlines BL among the plurality of bitlines BL. In some embodiments, the buried contacts BC may be arranged in rows along the first and second horizontal directions X and Y. A plurality of landing pads LP may be arranged on the buried contacts BC. The landing pads LP may be connected to a plurality of capacitor structures CP.

The buried contacts BC and the landing pads LP may serve to connect lower electrodes of the capacitor structures CP to the active regions ACT. At least parts of the landing pads LP may vertically overlap with the buried contacts BC. At least parts of the capacitor structures CP may vertically overlap with the landing pads LP.

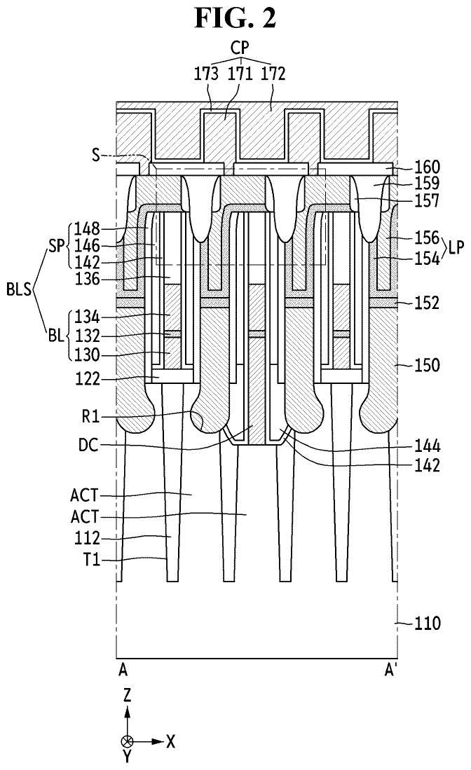

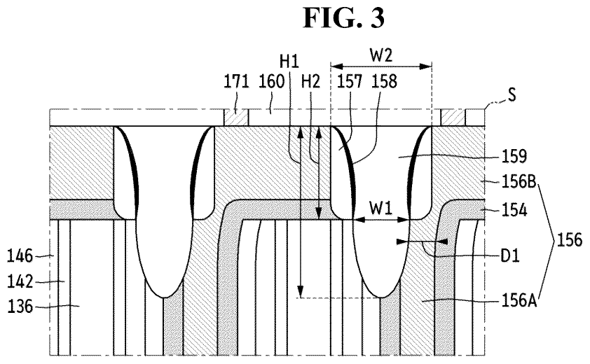

FIG. 2 is an exemplary cross-sectional view taken along A-A′ of FIG. 1. FIG. 3 is an enlarged view of region S in FIG. 2.

Referring to FIG. 2, the semiconductor memory device according to some embodiments may include a substrate 110, contact plugs 150, bitline structures BLS, landing pads LP, spacer patterns 157, an oxide film 158, separation patterns 159, and capacitor structures CP.

Referring to FIG. 2, the semiconductor memory device according to some embodiments may include a substrate 110 in which a plurality of active regions ACT are defined by an isolation film 112. The isolation film 112 may be formed in device isolation trenches T1 formed in the substrate 110.

The substrate 110 may include silicon (Si), for example, monocrystalline Si, polycrystalline Si, or amorphous Si. For example, the substrate 110 may include a semiconductor element such as Si or germanium (Ge), or a compound semiconductor such as SiGe, SiC, GaAs, InAs, or InP. In some embodiments, the substrate 110 may include conductive regions such as doped wells or doped structures. The isolation film 112 may be formed of an oxide film, a nitride film, or a combination thereof. The wordlines WL illustrated in FIG. 1 may be embedded in the substrate 110.

A buffer layer 122 may be formed on the substrate 110. The buffer layer 122 may cover the upper surfaces of the active regions ACT and the isolation film 112. The buffer layer 122 may contact the upper surfaces of the active regions ACT and the isolation film 112. The buffer layer 122 may include a first silicon oxide film, a silicon nitride film, and a second silicon oxide film sequentially formed on the substrate 110, but is not limited thereto.

A plurality of bitlines BL extending in parallel along the second horizontal direction Y may be arranged on the buffer layer 122. The bitlines BL may be spaced apart from each other along the first horizontal direction X. Direct contacts DC may be disposed on parts of the active regions ACT. The direct contacts DC may contact the active regions ACT. The bitlines BL may be respectively connected to the active regions ACT through the direct contacts DC. The direct contacts DC may include Si, Ge, W, WN, Co, Ni, Al, Mo, Ru, Ti, TiN, Ta, TaN, Cu, or a combination thereof. In some embodiments, the direct contacts DC may include doped polysilicon.

The bitlines BL may each include a lower conductive layer 130, an intermediate conductive layer 132, and an upper conductive layer 134 sequentially formed on the substrate 110. For example, the intermediate conductive layer 132 may contact an upper surface of the lower conductive layer 130, and the upper conductive layer 134 may contact an upper surface of the intermediate conductive layer 132. The upper surfaces of the bitlines BL may be covered with insulating capping patterns 136. The insulating capping patterns 136 may be disposed on the upper conductive layer 134. For example, the upper conductive layer 134 may contact an upper surface of the intermediate conductive layer 132. The upper surface of the lower conductive layer 130 and the upper surfaces of the direct contacts DC may be disposed on the same plane.

FIG. 2 illustrates that each of the plurality of bitlines BL has a triple conductive layer structure including a lower conductive layer 130, an intermediate conductive layer 132, and an upper conductive layer 134, but the present disclosure is not limited thereto. Alternatively, for example, the bitlines BL may each be formed to have a structure where a single conductive layer, two conductive layers, or four or more conductive layers are stacked.

In some embodiments, the lower conductive layer 130 may be formed of a doped polysilicon film. The intermediate conductive layer 132 and the upper conductive layer 134 may each include a layer containing Ti, TiN, TiSiN, tungsten (W), WN, tungsten silicide (WSiₓ), tungsten silicon nitride (WSiₓN_{y}), ruthenium (Ru), or a combination thereof. For example, the intermediate conductive layer 132 may include a TiN film and/or a TiSiN film, and the upper conductive layer 134 may include a Ti, TiN, W, WN, WSiₓN_{y}, Ru, or a combination thereof. The insulating capping patterns 136 may each be formed of a silicon nitride film.

In some regions of the substrate 110, a plurality of recess spaces R1 may be formed in the active regions ACT. The recess spaces R1 may be respectively filled with a plurality of contact plugs 150. The contact plugs 150 may have a column shape extending in a vertical direction Z from the recess spaces R1. The contact plugs 150 may respectively contact the active regions ACT. The lower ends of the contact plugs 150 may be positioned at a lower level than the upper surface of the substrate 110 to be embedded within the substrate 110. The contact plugs 150 may include impurity-doped semiconductor patterns but are not limited thereto.

In the semiconductor memory device according to some embodiments, one direct contact DC and a pair of contact plugs 150 facing each other across the direct contact DC may be connected to different active regions ACT among the plurality of active regions ACT.

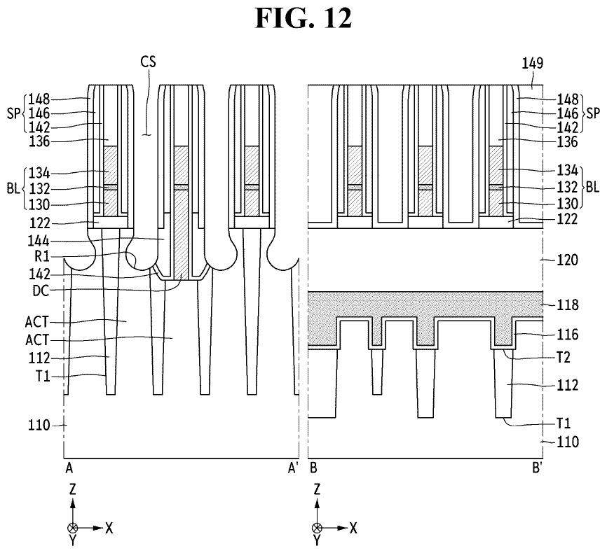

A plurality of contact plugs 150 may be arranged in a row along the second horizontal direction Y between a pair of adjacent bitlines BL selected among the plurality of bitlines BL. Insulating fences (e.g., insulating fences 149 in FIG. 12) may be disposed between the contact plugs 150 arranged in a row along the second horizontal direction Y. The contact plugs 150 may be electrically isolated from each other by a plurality of insulating fences 149. The insulating fences 149 may have a column shape extending in the vertical direction Z on the substrate 110. In some embodiments, the insulating fences 149 may be formed of a silicon nitride film.

A plurality of metal silicide films 152 and a plurality of landing pads LP may be disposed on the contact plugs 150. The landing pads LP may extend longitudinally in the vertical direction Z above the contact plugs 150, respectively. The landing pads LP may be connected to the contact plugs 150 through the metal silicide films 152. For example, the landing pads LP may contact upper surfaces of the plurality of metal silicide films 152, and the plurality of metal silicide films 152 may contact upper surfaces of the contact plugs 150.

The landing pads LP may each include a conductive barrier film 154 and a metal film 156. In some embodiments, the conductive barrier film 154 may include at least one of titanium (Ti) and titanium nitride (TiN), and the metal film 156 may include W. The landing pads LP may have island-shaped patterns when viewed in a planar view. In some embodiments, the metal silicide films 152 may include cobalt silicide, nickel silicide, or manganese silicide, but is not limited thereto.

The contact plugs 150 and the metal silicide films 152 may constitute the buried contacts BC of FIG. 1. The contact plugs 150, the metal silicide films 152, and the landing pads LP, which are sequentially arranged on the substrate 110, may form contact structures that are connected to the active regions ACT of the substrate 110 at locations near the bitlines BL in the first horizontal direction X.

Both sidewalls of the bitlines BL and both sidewalls of the insulating capping patterns 136 covering the upper surfaces of the bitlines BL may be covered with bitline spacer structures SP. A single bitline spacer structure SP may be interposed between one of the bitlines BL and a plurality of contact plugs 150 arranged in a row along the second horizontal direction Y near the one bitline BL. The bitline spacer structures SP may each include an inner insulating spacer 142, an intermediate insulating spacer 146, and an outer insulating spacer 148.

The inner insulating spacers 142 of the bitline spacer structures SP may contact the sidewalls of the bitline BL and the sidewalls of the direct contact DC. The inner insulating spacers 142 of the bitline spacer structures SP may include portions contacting the contact plugs 150. The inner insulating spacers 142 of the bitline spacer structures SP may be formed of a silicon nitride film.

The intermediate insulating spacers 146 may be interposed between the inner insulating spacers 142 and the outer insulating spacers 148 in the first horizontal direction X. The intermediate insulating spacers 146 may have sidewalls facing the bitlines BL across the inner insulating spacers 142, and sidewalls facing the contact plugs 150, the metal silicide films 152, and the landing pads LP across the outer insulating spacers 148. The intermediate insulating spacers 146 may each be formed of a silicon oxide film, an air spacer, or a combination thereof. In this specification, the term “air” may refer to ambient air or other gases present during the manufacture of the semiconductor memory device according to some embodiments.

The outer insulating spacers 148 may contact the sidewalls of the contact plugs 150, the sidewalls of the metal silicide films 152, and the sidewalls of the landing pads LP. The outer insulating spacers 148 may be spaced apart from the inner insulating spacers 142 across the intermediate insulating spacers 146. In some embodiments, the outer insulating spacers 148 may each be formed of a silicon nitride film.

The bitline spacer structures SP may extend parallel to the bitlines BL along the second horizontal direction Y. The insulating capping patterns 136 and the bitline spacer structures SP may form an insulating structure covering the upper surfaces and sidewalls of the bitlines BL. In this specification, the bitline structures BLS may refer to configurations including the bitlines BL and the bitline spacer structures SP.

Gap-fill insulating patterns 144 may be interposed between the direct contacts DC and the contact plugs 150. The gap-fill insulating patterns 144 may be spaced apart from the direct contacts DC across the inner insulating spacers 142. The gap-fill insulating patterns 144 may cover the sidewalls of the direct contacts DC and surround the direct contacts DC. The gap-fill insulating patterns 144 may contact the inner insulating spacers 142 and the contact plugs 150. In some embodiments, the gap-fill insulating patterns 144 may each be formed of a silicon nitride film.

The spacer patterns 157 may be disposed on the upper surfaces of the bitline structures BLS. The spacer patterns 157 may contact at least one sidewall of the landing pads LP. The spacer patterns 157 may contact the metal film 156. The spacer patterns 157 may include silicon nitride. The spacer patterns 157 may not contact the inner sidewalls of the bitline structures BLS. The spacer patterns 157 may contact the conductive barrier film 154 on the upper surfaces of the bitline structures BLS.

The oxide film 158 may be disposed between the separation patterns 159 and the spacer patterns 157 that will be described later. The oxide film 158 may not be disposed between the separation patterns 159 and the bitline structures BLS or between the separation patterns 159 and the landing pads LP. The oxide film 158 may include an oxide material.

The separation patterns 159 may be disposed between the spacer patterns 157. The separation patterns 159 may extend to the inner sidewalls of the bitline structures BLS. The separation patterns 159 may contact the inner sidewalls of the bitline structures BLS. The separation patterns 159 may contact the conductive barrier film 154 on the sidewalls of the bitline structures BLS.

The separation patterns 159 may include first portions that contact first inner sidewalls of the bitline structures BLS and first inner sidewalls of the respective landing pads LP, and second portions disposed on the first portions and contacting the oxide film 158. The first portions of the separation patterns 159 may be disposed up to a level of upper surfaces of the insulating capping patterns 136, and the second portions of the separation patterns 159 may be disposed at a level higher than the upper surfaces of the insulating capping patterns 136.

A maximum width W1 of the first portions of the separation patterns 159 may be smaller than a maximum width W2 of the second portions of the separation patterns 159. In example embodiments, the maximum width W1 of the first portions of the separation patterns 159 may be a width of the separation patterns 159 at a level of the upper surfaces of the insulating capping patterns 136. The width of the first portions of the separation patterns 159 may decrease closer to the substrate 110.

The first portions of the separation patterns 159 may be formed in first recesses within the bitline structures BLS. The spacer patterns 157 may be formed in second recesses within the landing pads LP. The width of the first recesses may be smaller than the width of the second recesses.

The separation patterns 159 may contact the sidewalls of first regions 156A. In the vertical direction Z, a length H1 by which the separation patterns 159 extend may be greater than a length H2 by which the spacer patterns 157 extend.

The oxide film 158 may not be disposed between the first portions of the separation patterns 159 and the first inner sidewalls of the bitline structures BLS, but may be disposed between the second portion of the separation pattern 159 and the spacer patterns 157.

The separation patterns 159 may be formed of or include silicon nitride.

The metal film 156 may include the first regions 156A on the sidewalls of the bitline structures BLS and second regions 156B on the upper surfaces of the bitline structures BLS. The spacer patterns 157 may contact the sidewalls of the second regions 156B.

A plurality of capacitor structures CP may be disposed on the landing pads LP. The capacitor structures CP may include a plurality of lower electrodes 171, a dielectric film 173, and an upper electrode 172. The dielectric film 173 may cover the lower electrodes 171. The dielectric film 173 may be disposed along the surfaces of the lower electrodes 171. For example, the dielectric film 173 may contact the lower electrodes 171. The upper electrode 172 may cover the dielectric film 173 and may face the lower electrodes 171 across the dielectric film 173. For example, the upper electrode 172 may contact the dielectric film 173.

The lower electrodes 171 may protrude upward in a direction away from the substrate 110. The lower electrodes 171 may have a pillar shape extending longitudinally upward along the vertical direction Z, but the present disclosure is not limited thereto. Alternatively, for example, the lower electrodes 171 may have a cup shape or a closed-bottom cylindrical cross-sectional structure.

The lower electrodes 171 may be disposed on capping layer 160. The lower electrodes 171 may include a portion extending between adjacent ones of capping layer 160. The lower electrodes 171 may contact upper and side surfaces of capping layer 160. The capping layer 160 may cover the separation patterns 159. For example, capping layer 160 may contact upper surfaces of the separation patterns 159. In example embodiments, capping layer 160 may cover and contact an entire upper surface of each of the separation patterns 159 and at least a portion of the second regions 156B of the metal film 156. The capping layer 160 may be formed of or include an insulating material. The capping layer 160 may include at least one of, but is not limited to, silicon oxide, silicon nitride, silicon carbonitride, and silicon boron nitride.

The lower electrodes 171 may include a first metal. The upper electrode 172 may include a second metal. In some embodiments, the second metal may be the same as the first metal. In other embodiments, the second metal may be different from the first metal.

The lower electrodes 171 and the upper electrode 172 may each include a metal film, a conductive metal oxide film, a conductive metal nitride film, a conductive metal oxynitride film, or a combination thereof. In some embodiments, the lower electrodes 171 and the upper electrode 172 may each include niobium (Nb), an oxide of Nb, a nitride of Nb, an oxynitride of Nb, Ti, an oxide of Ti, a nitride of Ti, an oxynitride of Ti, cobalt (Co), an oxide of Co, a nitride of Co, an oxynitride of Co, tin (Sn), an oxide of Sn, a nitride of Sn, an oxynitride of Sn, or a combination thereof. For example, the lower electrodes 171 and the upper electrode 172 may each include NbN, TiN, CON, SnO₂, or a combination thereof. In other embodiments, the lower electrodes 171 and the upper electrode 172 may each include TaN, TiAlN, TaAlN, V, VN, Mo, MoN, W, WN, Ru, RuO₂, SrRuO₃, Ir, IrO₂, Pt, PtO, SRO (SrRuO₃), BSRO ((Ba,Sr)RuO₃), CRO (CaRuO₃), LSCO ((La,Sr)CoO₃), or a combination thereof. However, the materials constituting the lower electrodes 171 and the upper electrode 172 are not limited to these examples.

The dielectric film 173 may be formed of a high-k dielectric film. The term “high-k dielectric film” as used herein refers to a dielectric film having a dielectric constant greater than that of a silicon oxide film. In some embodiments, the dielectric film 173 may be formed of a metal oxide that includes at least one metal selected from hafnium (Hf), zirconium (Zr), aluminum (Al), Nb, cerium (Ce), lanthanum (La), tantalum (Ta), and Ti. In some embodiments, the dielectric film 173 may have a single-layer structure formed of a single high-k dielectric film. In other embodiments, the dielectric film 173 may have a multi-layer structure including multiple high-k dielectric films. The single or multiple high-k dielectric films may be formed of HfO₂, ZrO₂, Al₂O₃, La₂O₃, Ta₂O₅, Nb₂O₅, CeO₂, TiO₂, GeO₂, or combinations thereof, but are not limited thereto.

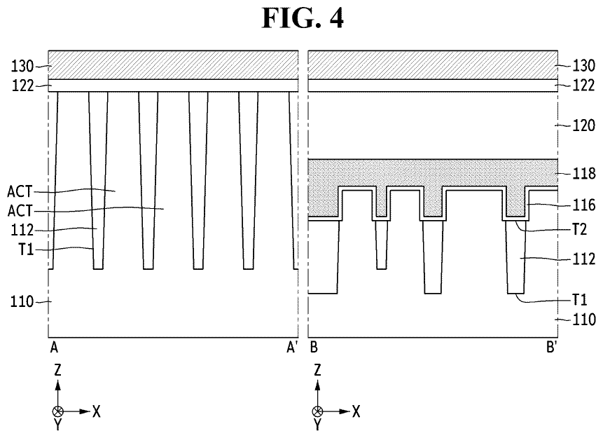

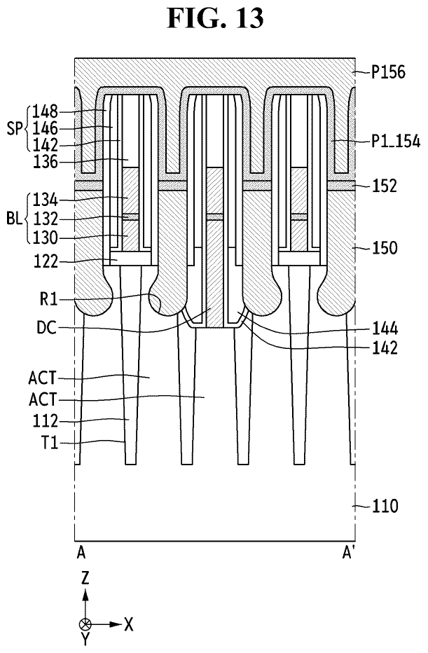

FIGS. 4 through 18 are diagrams for explaining intermediate steps of a method for manufacturing a semiconductor memory device according to some example embodiments. FIGS. 4 through 12 are cross-sectional views taken along lines A-A′ and B-B′ of FIG. 1. FIGS. 13 through 18 are cross-sectional views, taken along line A-A′ of FIG. 1, illustrating processes following that illustrated in FIG. 12. For convenience, overlapping descriptions with FIGS. 1 through 3 will not be repeated.

Referring to FIG. 4, device isolation trenches T1 may be formed in a substrate 110, and an isolation film 112 may be formed in the device isolation trenches T1. The isolation film 112 may define a plurality of active regions ACT in the substrate 110.

A plurality of wordline trenches T2 may be formed in the substrate 110. The wordline trenches T2 may extend parallel to each other along a first horizontal direction X and may have a line shape extending across the active regions ACT. To form the wordline trenches T2, which have steps at their bottoms, the isolation film 112 and the substrate 110 may be etched in separate etching processes such that the etching depths of the isolation film 112 and the substrate 110 may differ from each other. After cleaning the resultant structure with the wordline trenches T2 formed, a gate dielectric film 116, wordlines 118, and buried insulating films 120 may be sequentially formed in the wordline trenches T2. The wordlines 118 may correspond to the wordlines WL illustrated in FIG. 1.

The gate dielectric film 116 may be formed of at least one selected from a silicon oxide film, a silicon nitride film, a silicon oxynitride film, an oxide/nitride/oxide (ONO) film, and a high-k dielectric film having a dielectric constant greater than that of a silicon oxide film. The high-k dielectric film may be formed of HfO₂, Al₂O₃, HfAlO₃, Ta₂O₃, TiO₂, or combinations thereof. The wordlines 118 may each be formed of Ti, TiN, Ta, TaN, W, WN, TiSiN, WSiN, or a combination thereof. The buried insulating films 120 may each be formed of a silicon oxide film, a silicon nitride film, a silicon oxynitride film, or a combination thereof. An ion implantation process for forming a plurality of source/drain regions in the upper portions of the active regions ACT may be performed before or after forming the wordlines 118.

A buffer layer 122 and a lower conductive layer 130 may be sequentially formed on the substrate 110. The buffer layer 122 may cover the upper surfaces of the active regions ACT, the upper surface of the isolation film 112, and the buried insulating films 120. To form the buffer layer 122, a first silicon oxide film, a silicon nitride film, and a second silicon oxide film may be sequentially formed on the substrate 110, but the present disclosure is not limited thereto. The lower conductive layer 130 may be formed of a doped polysilicon film.

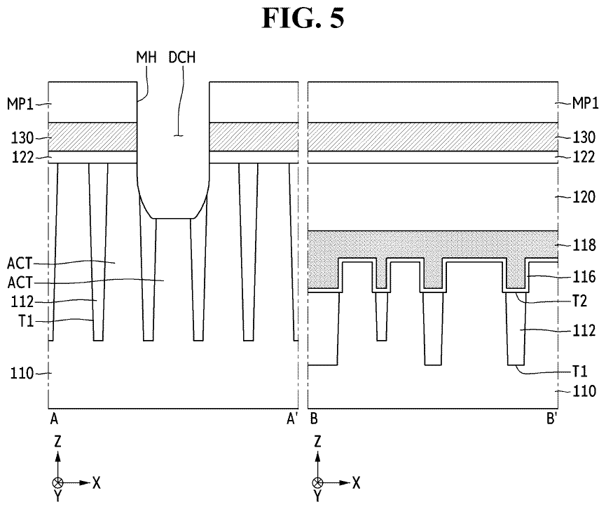

Referring to FIG. 5, a mask pattern MP1 may be formed on the lower conductive layer 130, and direct contact holes DCH may be formed by etching portions of the lower conductive layer 130 exposed through openings MH of the mask pattern MP1, as well as portions of the underlying buffer layer 122, substrate 110, and isolation film 112 to expose the active regions ACT of the substrate 110. The mask pattern MP1 may be formed of an oxide film, a nitride film, or combinations thereof, but is not limited thereto.

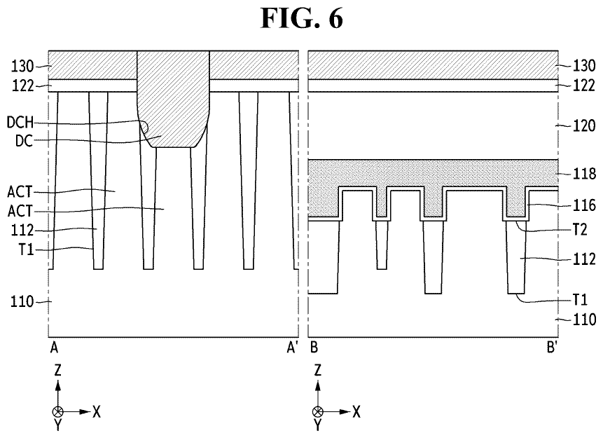

Referring to FIG. 6, the mask pattern MP1 may be removed, and direct contacts DC may be formed in the direct contact holes DCH.

To form the direct contacts DC, a doped polysilicon film thick enough to fill the direct contact holes DCH may be formed on the inner surfaces of the direct contact holes DCH and on the upper surface of the lower conductive layer 130. Then, unnecessary portions of the doped polysilicon film may be removed so that the doped polysilicon film remains only within the direct contact holes DCH. In some embodiments, the direct contacts DC may each be formed of a polysilicon film doped with an n-type dopant. The n-type dopant may be selected from phosphorus (P), arsenic (As), and antimony (Sb).

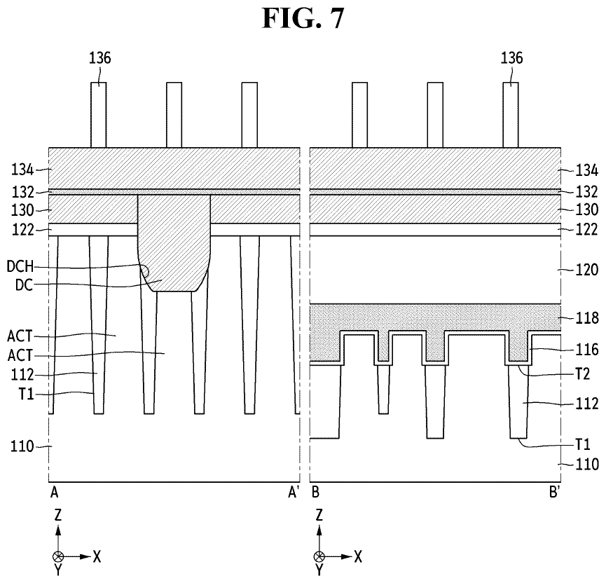

Referring to FIG. 7, an intermediate conductive layer 132, an upper conductive layer 134, and a plurality of insulating capping patterns 136 may be sequentially formed on the lower conductive layer 130 and the direct contacts DC. The insulating capping patterns 136 may be line patterns extending longitudinally along a second horizontal direction Y.

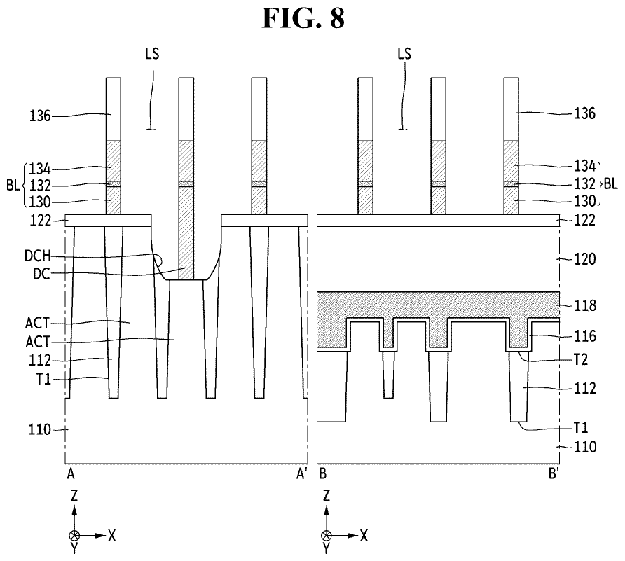

Referring to FIG. 8, a plurality of bitlines BL may be formed on the substrate 110 by etching portions of the upper conductive layer 134, the intermediate conductive layer 132, the lower conductive layer 130, and the direct contacts DC, using the insulating capping patterns 136 as an etching mask. The bitlines BL may include the remaining portions of the lower conductive layer 130, the intermediate conductive layer 132, and the upper conductive layer 134.

After forming the bitlines BL, portions of the direct contact holes DCH may be re-exposed around the direct contacts DC, and line spaces LS extending longitudinally along the second horizontal direction Y may be formed between the bitlines BL.

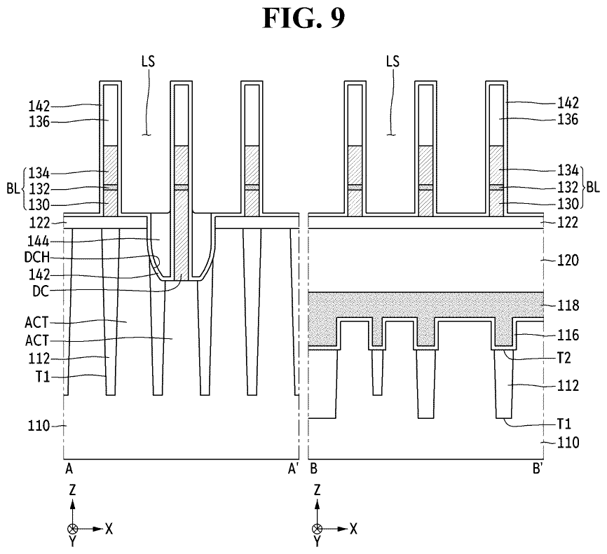

Referring to FIG. 9, inner insulating spacers 142 conformally covering the surfaces exposed by the line spaces may be formed in the line spaces LS, and gap-fill insulating patterns 144 filling the remaining spaces within the direct contact holes DCH may be formed on the inner insulating spacers 142.

The inner insulating spacers 142 may be formed to conformally cover the direct contacts DC, the lower conductive layer 130, the intermediate conductive layer 132, the upper conductive layer 134, and the insulating capping patterns 136. The inner insulating spacers 142 may each be formed of a silicon nitride film. The inner insulating spacers 142 may be formed using a chemical vapor deposition (CVD) process or an atomic layer deposition (ALD) process.

To form the gap-fill insulating patterns 144, a gap-fill insulating film (not illustrated) covering the sidewalls of the bitlines BL, the sidewalls of the insulating capping patterns 136, and the sidewalls of the direct contacts DC while filling the remaining spaces within the direct contact holes DCH may be formed using a CVD or ALD process. Thereafter, the gap-fill insulating film may be etched to form the gap-fill insulating patterns 144 from the remaining portions of the gap-fill insulating film.

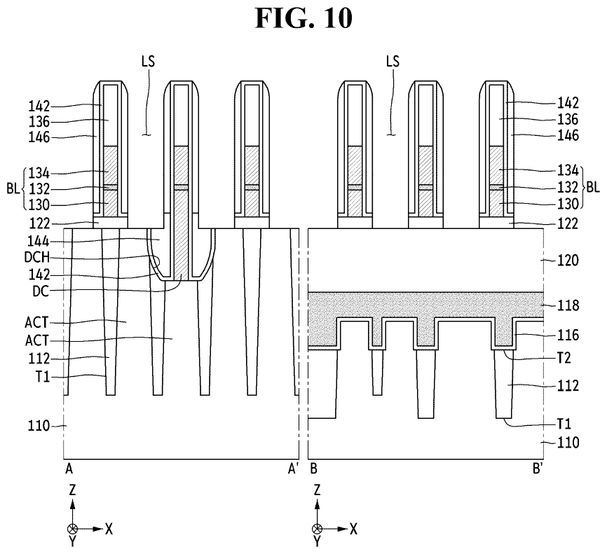

Referring to FIG. 10, an intermediate insulating spacer film (not illustrated) covering the exposed surfaces may be conformally formed using a CVD or ALD process, and may then be anisotropically etched to form a plurality of intermediate insulating spacers 146 from the intermediate insulating spacer film.

During the anisotropic etching of the intermediate insulating spacer film to form the intermediate insulating spacers 146, portions of the inner insulating spacers 142 and portions of the buffer layer 122 may be removed. As a result, portions of the substrate 110, portions of the inner insulating spacers 142, and portions of the gap-fill insulating patterns 144 may be exposed through the line spaces LS. The intermediate insulating spacers 146 may cover the sidewalls of the bitlines BL and the insulating capping patterns 136 over the inner insulating spacers 142. In some embodiments, the intermediate insulating spacers 146 may each be formed of a silicon oxide film.

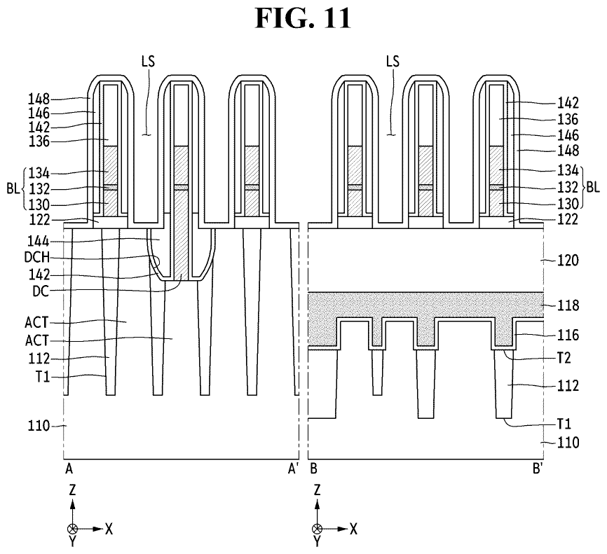

Referring to FIG. 11, outer insulating spacers 148 may be formed. A CVD or ALD process may be used to form the outer insulating spacers 148.

Referring to FIG. 12, a plurality of insulating fences 149 may be formed in the line spaces LS defined by the outer insulating spacers 148, between the bitlines BL, to divide the line spaces LS into a plurality of contact spaces CS.

The insulating fences 149 may be formed to overlap in a vertical direction Z with the wordlines 118 over the wordlines 118. The insulating fences 149 may be formed of silicon nitride. In some embodiments, during the formation of the insulating fences 149, portions of the insulating capping patterns 136 and portions of the surrounding insulating films may be consumed so that their height may be reduced.

Thereafter, portions of the structures exposed through the contact spaces CS may be removed to form a plurality of recess spaces R1 that expose the active regions ACT of the substrate 110 between the bitlines BL. The recess spaces R1 may be formed using an anisotropic etching process, or a combination of anisotropic etching and isotropic etching processes. For example, portions of the outer insulating spacers 148 and portions of the underlying substrate 110 exposed at the bottom of the contact spaces CS may be anisotropically etched, and then the exposed portions of the active regions ACT of the substrate 110 may be isotropically etched to form the recess spaces R1. The recess spaces R1 may be respectively connected to the contact spaces CS. During the etching process for forming the recess spaces R1, portions of the inner insulating spacers 142 and portions of the gap-fill insulating patterns 144 near the upper surface of the substrate 110 may be consumed.

Portions of the active regions ACT of the substrate 110, portions of the inner insulating spacers 142, and portions of the gap-fill insulating patterns 144 may be exposed through the recess spaces R1. After the formation of the recess spaces R1, the inner insulating spacers 142, the intermediate insulating spacers 146, and the outer insulating spacers 148 remaining on both sidewalls of the bitlines BL may form bitline spacer structures SP.

Referring to FIG. 13, a plurality of contact plugs 150 filling the recess spaces R1 and portions of the contact spaces CS, between the bitlines BL, may be formed. A plurality of metal silicide films 152 may be formed on the contact plugs 150, and a first pre-barrier film P1_154 and a pre-metal film P156 sequentially covering the remaining spaces of the contact spaces CS, the insulating capping patterns 136, and the bitline spacer structures SP may be formed.

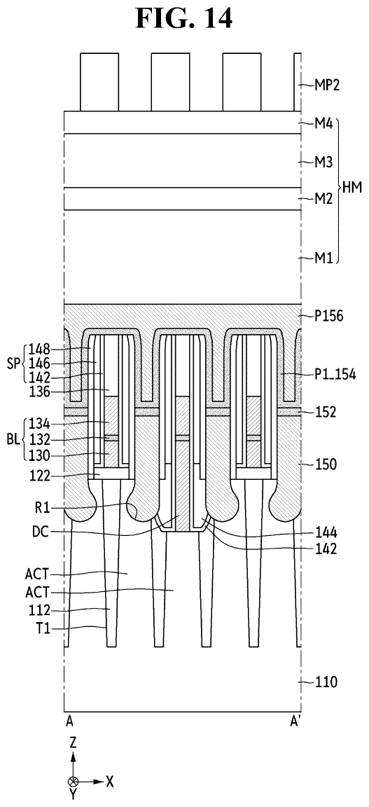

Referring to FIG. 14, a hardmask structure HM may be formed on the pre-metal film P156, and mask patterns MP2 may be formed on the hardmask structure HM.

The hardmask structure HM may have a laminated structure of multiple hardmask layers formed of different materials. In some embodiments, the hardmask structure HM may include a first hardmask layer M1, a second hardmask layer M2, a third hardmask layer M3, and a fourth hardmask layer M4 sequentially stacked on the metal film 156. For example, the first hardmask layer M1 may be formed of an amorphous carbon layer (ACL), the second hardmask layer M2 may be formed of amorphous polysilicon, the third hardmask layer M3 may be formed of a spin-on hardmask (SOH) material, and the fourth hardmask layer M4 may be formed of SiON. However, the present disclosure is not limited to this example.

The mask patterns MP2 may each be formed of a photoresist pattern. The mask patterns MP2 may be spaced apart from each other.

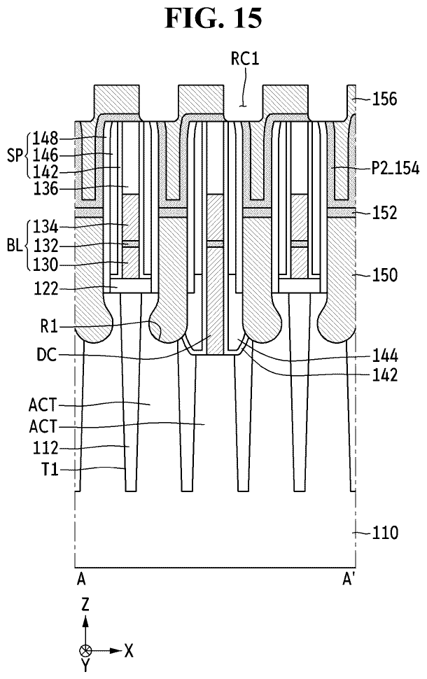

Referring to FIG. 15, the mask patterns MP2 may be used as an etching mask to etch at least parts of the fourth hardmask layer M4, the third hardmask layer M3, the second hardmask layer M2, the first hardmask layer M1, the pre-metal film P156, and the first pre-barrier film P1_154 to form a metal film 156 having third recesses RC1 exposing portions of the bitline structures BLS. The third recesses RC1 may expose portions of the inner sidewalls of the metal film 156, portions of the inner sidewalls of the second pre-barrier film P2_154, and portions of the upper surfaces of the bitline structures BLS.

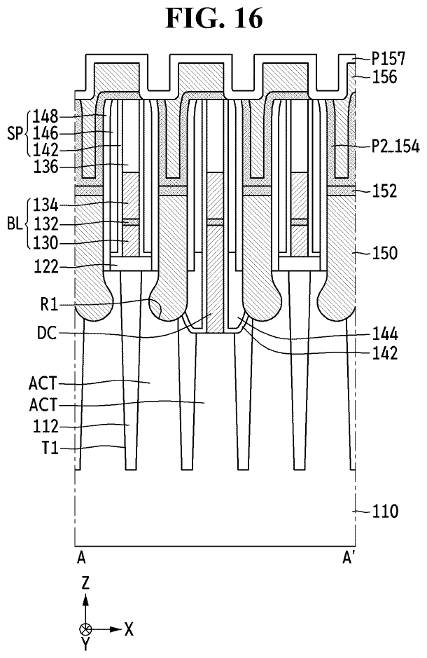

Referring to FIG. 16, a pre-spacer film P157 may be formed along the surface of the metal film 156. The pre-spacer film P157 may be formed on portions of the inner sidewalls of the metal film 156, portions of the inner sidewalls of the second pre-barrier film P2_154, and portions of the upper surfaces of the bitline structures BLS. The pre-spacer film P157 may include silicon nitride.

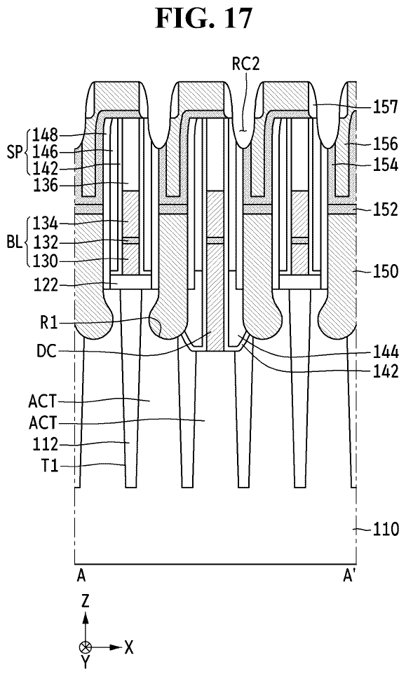

Referring to FIG. 17, at least parts of the pre-spacer film P157, bitline structures BLS, and second pre-barrier film P2_154 may be removed to form fourth recesses RC2 that expose portions of the inner sidewalls of the bitline structures BLS and portions of the second pre-barrier film P2_154. Spacer patterns 157 spaced apart from each other may be formed by the fourth recesses RC2. Portions of the inner sidewalls of the upper bitline structures BLS, portions of the inner sidewalls of the conductive

barrier film 154, and portions of the inner sidewalls of the metal film 156 may be further exposed by the fourth recesses RC2. The width of the fourth recesses RC2 may be smaller than the width of the third recesses RC1.

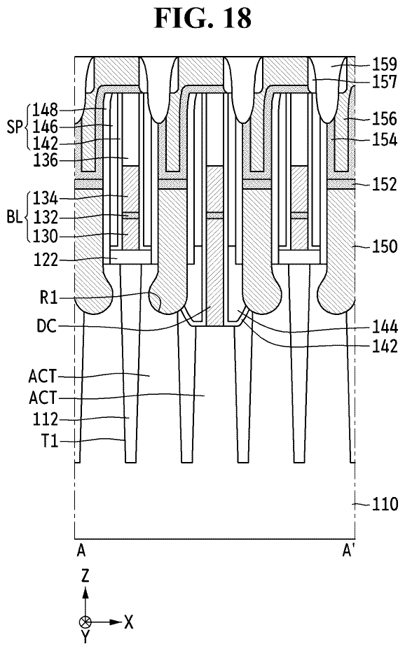

Referring to FIG. 18, separation patterns 159 may be formed between the spacer patterns 157 within the fourth recesses RC2. The separation patterns 159 may include silicon nitride. An oxide film 158 may be interposed on the spacer patterns 157. The oxide film 158 may not be formed between the bitline structures BLS and the separation patterns 159.

Referring to FIG. 2, capping layer 160 and a plurality of capacitor structures CP may formed on the metal film 156 and the separation patterns 159.

In some embodiments, the fourth recesses RC2, having a smaller width than the third recesses RC1, may be formed, and the separation patterns 159 may be formed within the fourth recesses RC2. As a result, a width D1 of the metal film 156 between the separation patterns 159 and the bitline structures BLS may be further secured to accommodate the spacer patterns 157. Consequently, a semiconductor memory device with improved reliability and performance may be provided.

Although the embodiments of the present disclosure have been described with reference to the accompanying drawings, the present disclosure is not limited to these embodiments and may be manufactured in various other forms. Those skilled in the art will understand that the technical scope or essential characteristics of the present disclosure can be modified and implemented in other specific forms without departing from the spirit of the invention. Therefore, the embodiments described above should be understood as being illustrative in all respects and not limiting.

What is claimed is:

1. A semiconductor memory device comprising:
a substrate having an active region and extending in a first horizontal direction and a second horizontal direction intersecting each other;
a contact plug connected to the active region;
a bitline structure disposed adjacent to the contact plug in the first horizontal direction and extending along the second horizontal direction;
a landing pad disposed on the bitline structure and connected to the contact plug;
spacer patterns spaced apart from each other on an upper surface of the bitline structure and contacting at least one sidewall of the landing pad;
a separation pattern extending to inner sidewalls of the bitline structure between the spacer patterns; and
an oxide film disposed between the spacer patterns and the separation pattern,
wherein the oxide film is not disposed between the separation pattern and the bitline structure.

2. The semiconductor memory device of claim 1, wherein the separation pattern contacts the inner sidewalls of the bitline structure.

3. The semiconductor memory device of claim 1, wherein the landing pad includes a first region on sidewalls of the bitline structure and a second region on the upper surface of the bitline structure.

4. The semiconductor memory device of claim 3, wherein the spacer patterns contact the second region.

5. The semiconductor memory device of claim 3, wherein the separation pattern contacts the first region.

6. The semiconductor memory device of claim 1, wherein a length of the separation pattern in a vertical direction is greater than a length of each of the spacer patterns in the vertical direction.

7. The semiconductor memory device of claim 1, wherein the landing pad includes a barrier film contacting sidewalls and upper surfaces of the bitline structure, and a metal film on the barrier film.

8. The semiconductor memory device of claim 7,
wherein the separation pattern includes a first portion contacting the barrier film and the inner sidewalls of the bitline structure, and a second portion contacting the spacer patterns, and
wherein a maximum width of the first portion is smaller than a maximum width of the second portion.

9. The semiconductor memory device of claim 7,
wherein the barrier film includes titanium nitride, and
wherein the metal film includes tungsten.

10. The semiconductor memory device of claim 1, wherein the spacer patterns and the separation pattern each include silicon nitride.

11. A semiconductor memory device comprising:
a substrate having an active region and extending in a first horizontal direction and a second horizontal direction perpendicularly intersecting each other;
contact plugs connected to the active region;
bitline structures alternately arranged with the contact plugs in the first horizontal direction and extending along the second horizontal direction;
landing pads respectively connected to the contact plugs on the bitline structures, and including a barrier film in contact with sidewalls and upper surfaces of the bitline structures, and a first metal film on the barrier film;
a second metal film disposed between the contact plugs and the landing pads;
spacer patterns spaced apart from each other on the upper surfaces of the bitline structures and contacting sidewalls of the landing pads;
a separation pattern extending along a vertical direction to an inner sidewall of one of the bitline structures, between the spacer patterns; and
an oxide film between the spacer patterns and the separation pattern,
wherein the separation pattern includes a first portion in contact with the inner sidewall of the one of the bitline structures and an inner sidewall of one of the landing pads, and a second portion disposed on the first portion and in contact with the oxide film.

12. The semiconductor memory device of claim 11, wherein the oxide film is not disposed between the first portion and the inner sidewall of the one of the bitline structures and is disposed between the second portion and the spacer patterns.

13. The semiconductor memory device of claim 11, wherein the spacer patterns do not contact inner sidewalls of the bitline structures, and contact the barrier film on the upper surfaces of the bitline structures.

14. The semiconductor memory device of claim 11,
wherein the first portion is formed in a first recess within the bitline structures,
wherein the spacer patterns are formed in second recesses within the landing pads, and
wherein a width of the first recess is smaller than a width of the second recesses.

15. The semiconductor memory device of claim 11, wherein a width of the first portion decreases closer to the substrate.

16. The semiconductor memory device of claim 11, further comprising:
a capacitor structure on the landing pads, the capacitor structure including a lower electrode protruding away from the substrate along the vertical direction, a dielectric film disposed along a surface of the lower electrode, and an upper electrode on the dielectric film.

17. A method for manufacturing a semiconductor memory device, the method comprising:
forming a bitline structure extending along a first horizontal direction, on a substrate;
forming a contact plug adjacent to the bitline structure in a second horizontal direction and connected to an active region, on the substrate;
forming a landing pad including a pre-barrier film, extending along sidewalls and an upper surface of the bitline structure, and a pre-metal film on the pre-barrier film, on the contact plug;
forming a metal film having a first recess that exposes a portion of the bitline structure, by removing at least portions of the pre-metal film and the pre-barrier film;
forming a pre-spacer film within the first recess, along a surface of the metal film;
forming spacer patterns having second recesses that expose inner sidewalls of the bitline structure, by removing at least portions of the pre-spacer film, the bitline structure, and the pre-barrier film;
forming a separation pattern between the spacer patterns, within the second recesses; and
forming an oxide film on the spacer patterns,
wherein the oxide film is not formed between the bitline structure and the separation pattern.

18. The method of claim 17, wherein a width of the second recesses is smaller than a width of the first recess.

19. The method of claim 17, wherein the pre-spacer film and the separation pattern each include silicon nitride.

20. The method of claim 17,
wherein the pre-barrier film includes titanium nitride, and
wherein the pre-metal film includes tungsten.
